(19) United States
(12) Patent Application Publication
(10) Pub. No.: US 2003/0024900 A1
(43) Pub. Date: Feb. 6, 2003

(54) Variable aspect ratio plasma source

(75) Inventor: Wayne L. Johnson, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TOKYO ELECTRON LIMITED, Tokyo (JP)

(21) Appl. No.: 10/195,553

(22) Filed: Jul. 16, 2002

Related U.S. Application Data
(60) Provisional application No. 60/307,183, filed on Jul. 24, 2001.

(51) Int. Cl. C23C 16/00; C23F 1/00; H01L 21/461; G01L 21/30

(52) U.S. Cl. 216/59; 156/345.24; 438/714; 156/345.47; 118/712; 118/723 E

(57) ABSTRACT

A method and system for adjusting a height-to-diameter ratio of a plasma processing chamber, either dynamically or before substrate processing, to control a uniformity of a plasma and/or match a uniformity of a plasma to at least one of a process type and a wafer configuration and/or type. By adjusting the height of the chamber, the position of electrons near a chamber wall can be moved toward a center of the chamber and vice versa.

### CROSS-REFERENCE TO RELATED APPLICATIONS

This application is related to and claims priority under 35 U.S.C. 119(e) to U.S. provisional application serial No. 60/307,183, filed Jul. 24, 2001, the entire contents of which are herein incorporated by reference.

### FIELD OF THE INVENTION

The present invention is related to plasma processing systems, particularly to a plasma processing system, which uses variable aspect ratio plasma source.

### BACKGROUND OF THE INVENTION

Manufacturers of semiconductor integrated circuits (IC) are faced with severe competitive pressure to improve their products. This pressure in turn is driving the manufacturers of the equipment used by IC manufacturers to improve the performance of their equipment. One particular type of tool that is widely used, and that is therefore particularly susceptible to these competitive pressures, is the plasma reactor. These reactors can be used to remove material, or (with modifications) they can be used to deposit material.

The mechanisms for either deposition or removal are complex, but in either case, it is essential to control the physical processes at the surface of the wafer. Control of these processes is the focus of significant technological development. Etch uniformity is a particular concern, and the manufacturer of plasma reactors that can improve overall uniformity enhances its potential for increasing market share. Current plasma reactors do not provide adequate etch uniformity over a wide range of processes.

In fact, in known plasma sources, plasma density uniformity is often related to a plasma source's height-to-diameter aspect ratio. As the height-to-diameter aspect ratio of the plasma source increases, the electron density at the center of the source increases. Conversely, as the height-to-diameter aspect ratio decreases, the electron density at the edges of the source increases.

In high height-to-diameter aspect ratio cylindrical plasma sources, gaseous species can easily diffuse to the center of the source. In general, a shortcoming of high aspect ratio plasma sources is a spatially non-uniform plasma density except for a narrow range of process conditions (e.g. narrow range of pressure). In particular, for low pressure (usually less than 50 mTorr), the plasma density in an inductively coupled plasma (ICP) source tends to be greatest in the center of the chamber and lowest at the edge of the chamber. On the contrary, the inverse can be true for higher pressures (i.e. greater than 50 mTorr). In fact, the narrow range of pressure wherein the plasma density is spatially homogeneous is sensitive to the process chemistry, gas species, etc., and so the optimal pressure may vary from one process to another.

Various patents and articles describe plasma systems, including: U.S. Pat. Nos. 6,042,687, 5,716,485, and 6,020,570.

U.S. Pat. No. 6,042,687 entitled “Method and apparatus for improving etch and deposition uniformity in plasma semiconductor processing,” assigned to Lam Research Corp. (Fremont, Calif.), describes a plasma processing system and method for processing substrates such as by chemical vapor deposition or etching. The system utilizes a secondary gas concentrated near the periphery of the substrate, improving etching/deposition uniformity across the substrate surface.

U.S. Pat. No. 5,716,485 entitled “Electrode designs for controlling uniformity profiles in plasma processing reactors,” assigned to Varian Associates Inc. (Palo Alto, Calif.), describes an electrode design for reducing the problem of non-uniform etch in large diameter substrates. The electrode opposite the substrate being etched in a plasma reactor can be tailored as to its shape so as to control the uniformity of the etching across the substrate. This is achieved with a number of generally dome-shaped electrode structures including generally cone-shaped electrodes, generally pyramid-shaped electrodes and generally hemispherically-shaped electrodes. The dome-shaped electrodes serve to disperse the high concentration of ions from the center of the reactor out toward the periphery of the substrate and thereby even out the ion density distribution across the substrate being etched. The electrodes are useable in diode plasma reactors, triode plasma reactors and ICP plasma reactors.

U.S. Pat. No. 6,020,570 entitled “Plasma Processing Apparatus,” assigned to Mitsubishi Denki Kabushiki Kaisha (Tokyo, Japan), describes an electrode design for reducing the problem of non-uniform etch in large diameter substrates. The electrode opposite the substrate being etched in a plasma reactor can be tailored as to its shape so as to control the uniformity of the etching across the substrate. This is achieved with a number of generally ring-shaped electrode structures.

In current systems, once a wafer is loaded into a plasma reactor for a given process step, the reactor may require parameter changes to achieve uniform plasma density for the current wafer process. Current etch processes rely on one or two adjustment parameters to reduce wafer edge effects. As wafers with different film stacks are processed, these parameters must be adjusted also from one cassette of wafers (i.e., 25 wafers) to the next. Adjustments are required to sustain a desired wafer etch profile as the chamber changes due to accumulated depositions, temperature, or electrode erosion. These types of adjustment processes are time-intensive and costly.

What is needed is a more time-efficient and cost-effective system for increasing the uniformity in a plasma processing reactor.

### SUMMARY OF THE INVENTION

Accordingly, it is an object of the present invention to increase uniformity in a plasma processing reactor by utilizing a variable aspect ratio (VAR) plasma source. In one embodiment, the uniformity (of the plasma or electron density) is controlled (either generally or in the radial direction) using feedback, which enables the aspect ratio of the plasma reactor to be dynamically controlled.

It is another object of the present invention to enable plasma source parameters to be varied over a wide range of wafer compositions, configurations and/or processes while maintaining radial plasma density uniformity.

It is a further object of the present invention to dynamically adjust a height-to-diameter ratio of a VAR plasma source for different wafer processes.

It is another object of the present invention to provide a plasma source useable over a wide range of wafer compositions, configurations and/or processes without varying other more dominant process parameters (e.g., the pressure).

It is another object of the present invention to provide a plasma source that can change processes dynamically, that is, to etch or deposit stacks of material and tune the process optimally for each layer.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 illustrates a simplified block diagram of a plasma processing system according to the present invention;

FIG. 2 illustrates a simplified cross-sectional view of a variable aspect ratio (VAR) plasma source according to the present invention;

FIG. 3 illustrates an expanded view of a vertically translatable gas injection electrode for a VAR plasma source according to the present invention; and

FIG. 4 illustrates a flowchart illustrating a method of using the variable aspect ratio plasma source according to the present invention.

### DETAILED DESCRIPTION OF THE PREFERRED EMBODIMENT

The present invention is directed to a method and apparatus for controlling plasma formed in a plasma reactor (e.g., an inductively coupled plasma reactor) having a (grounded) anode, a bias electrode which serves as the substrate holder and plasma coupling device (e.g., an inductive coil that surrounds the cylindrical geometry). In particular, a Variable Aspect Ratio (VAR) Plasma Source is designed with a variable height and is moved vertically within the plasma reactor to correct for process changes over a wide range of etching processes and deposition processes.

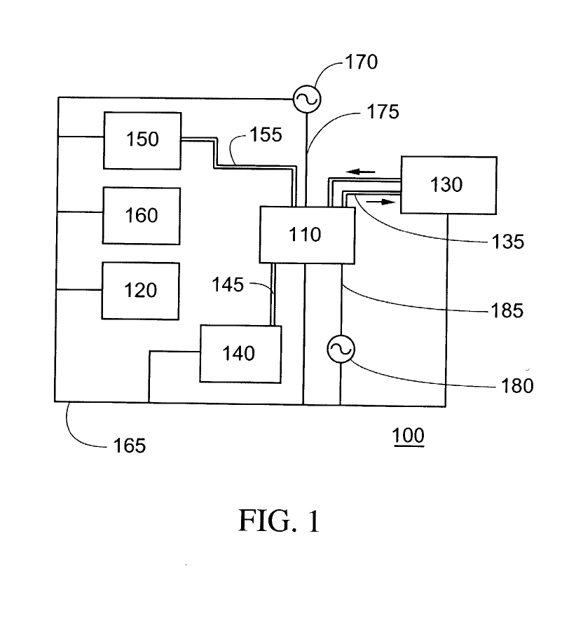

FIG. 1 illustrates a simplified block diagram of a plasma processing system according to the present invention. FIG. 1 shows a plasma processing system from a high-level perspective. Plasma processing system 100 comprises plasma reactor 110, wafer handling and robotics system 120, cooling system 130, pumping system 140, gas supply system 150, controller 160, first RF generator 170, first matching network 172, second RF generator 180, and second matching network 182.

Plasma processing system 100 further includes communication line 165, gas supply line 155, cooling lines 135, vacuum line 145, first RF transmission line 175, and second RF transmission line 185.

Controller 160 is operatively coupled via communication line 165 to gas supply system 150, wafer handling and robotics system 120, cooling system 130, pumping system 140, first RF generator 170, first matching network 172, second RF generator 180, second matching network 182, and plasma reactor 110.

In a preferred embodiment, plasma reactor 110 is pneumatically coupled to pumping system 140 via vacuum line 145. For example, a control valve is used, and the controller monitors the valve position. Plasma reactor 110 is electrically coupled to first RF generator 170 via first matching network 172 and first RF transmission line 175. Plasma reactor 110 is electrically coupled to second RF generator 180 via second matching network 182 and second RF transmission line 185. Controller 160 monitors and controls matching networks using tunable elements in the matching networks. For example, tuning parameters associated with the tunable elements can be used to determine plasma impedances and operating points.

Plasma reactor 110 is hydraulically coupled to cooling system 130 via cooling lines 135. Plasma reactor 110 is fluidly coupled to gas supply system 150 via gas supply line 155. Plasma reactor 110 is operatively coupled to wafer handling and robotics system 120 via a robotic arm (not shown).

Controller 160 (e.g., a computer controller) includes memory to store process instructions. In operation, upon command from controller 160 and in accordance with the process instructions stored in the memory of controller 160, wafer handling and robotics system 120 places a silicon wafer to be processed into plasma reactor 110. The aspect ratio of plasma reactor 110 is adjusted. Pumping system 140 pumps down plasma reactor 110. Gas from gas supply system 150 is introduced to plasma reactor 110 according to a pre-determined gas mixture recipe. Then, first RF generator 170 couples power to plasma reactor 110, which, in the presence of an ionizable gas at a pre-determined pressure within plasma reactor 110, creates a plasma that provides a population of ions and chemical environment suitable for etching the wafer. Second RF generator 180 couples power to the substrate holder to provide a bias suitable for attracting positively charged ions to the substrate surface to energize the surface etch chemistry. Cooling system 130 provides cooling for the plasma reactor 110 as the wafer is etched.

Controller 160 monitors and controls operational parameters for plasma reactor 110. For example, controller 160 can provide instructions to plasma reactor 110 to adjust the aspect ratio; to cooling system 130 to stabilize the temperature of the reactor wall and/or chuck; to gas supply system 150 to change the process gas; to first RF generator 170 to change the power being supplied to the plasma; and/or to second RF generator 180 to change the power being supplied to the plasma.

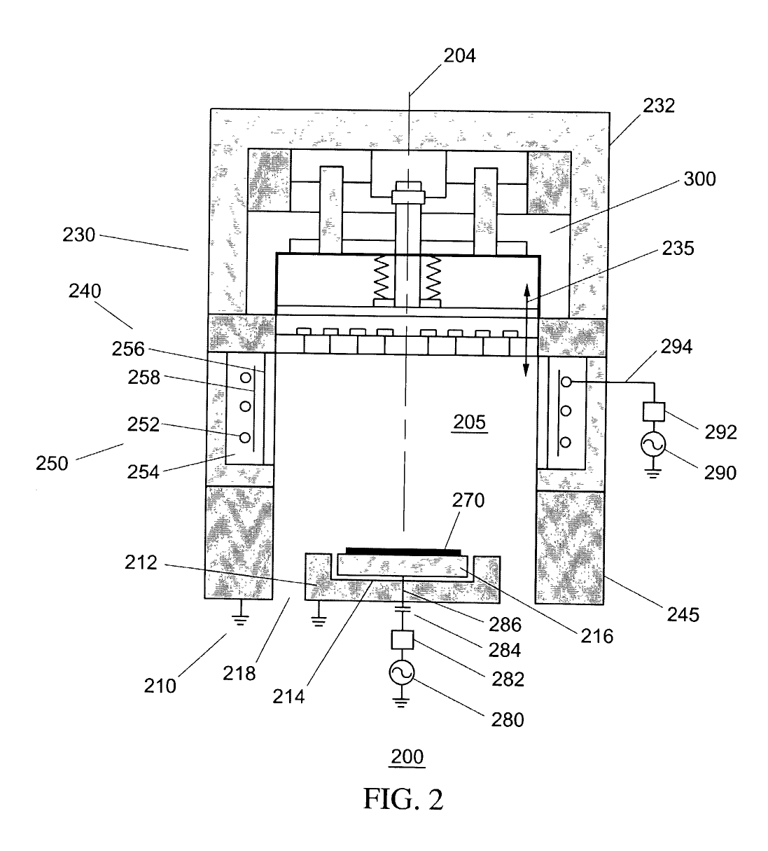

FIG. 2 illustrates a simplified cross-sectional view of a variable aspect ratio (VAR) plasma source according to the present invention. In a preferred embodiment, plasma reactor 110 (FIG. 1) comprises VAR plasma source 200.

VAR plasma source 200 includes chuck assembly 210, plasma source assembly 240, and VAR assembly 230. Plasma source assembly 240 is coupled to chuck assembly 210 and VAR assembly 230.

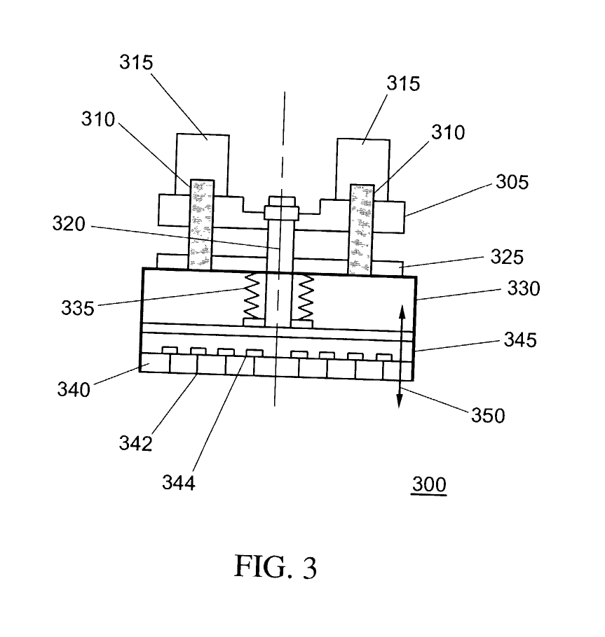

Plasma source assembly 240 includes process chamber 205, housing 245, and plasma source 250. Desirably, housing 245 is cylindrically shaped as shown in cross-section in FIG. 2 and comprises at least one outlet 218. For example, chuck assembly 210, housing 245, and VAR assembly 230 can be formed as cylinders and share a common axis 204. VAR assembly 230 comprises housing 232 and a vertically translatable gas inject electrode (to be discussed in greater detail in FIG. 3). VAR assembly 230 comprises temperature control (not shown) so that the temperature of the VAR assembly 230 can be monitored and controlled.

In a preferred embodiment, plasma source 250 comprises an inductively coupled plasma (ICP) source. In another embodiment, plasma source 250 can comprise an electrostatically shielded radio frequency (ESRF) plasma source. Plasma source 250 is coupled to housing 245.

As shown in FIG. 2, ESRF plasma source includes inductive coil 252, chamber 254, process tube 256, and electrostatic shield 258. Inductive coil 252 is generally fabricated from copper tubing and is desirably designed to be a quarter-wave resonator. Furthermore, inductive coil 252 is immersed within a bath of (dielectric) coolant such as Fluorinert and disposed about the perimeter of a dielectric process tube, which interfaces with the plasma processing region. The bath of coolant is recirculated in chamber 254 via an inlet flow of coolant and a corresponding outlet flow of coolant through coolant supply lines in order to provide plasma source cooling.

Electrostatic shield 258 is slotted and reduces capacitive coupling between the inductive coil 252 and the plasma processing region. Electrostatic shield 258 is generally fabricated from aluminum, and it is electrically grounded. RF power is coupled to the inductive coil 252 from first RF generator 290 through first impedance match network 292, and first transmission line 294. Desirably, the ICP source is utilized to generate a plasma from an ionizable gas.

Process tube 256 is generally fabricated from a dielectric material such as quartz or alumina. In addition, process tube 256 acts as a window for coupling RF power to the plasma, and it preserves the vacuum integrity of the chamber.

The electrical and mechanical design of an inductively coupled plasma source including the inductive coil, electrostatic shield, process tube, coil enclosure, impedance match network, tap location, etc. is well known to those of skill in the art. For further details, refer to U.S. Pat. No. 5,234,529, which is herein incorporated by reference in its entirety.

Chuck assembly 210 includes grounded chuck susceptor 212, insulator 214, and electrode 216. In a preferred embodiment, insulator 214 is used to electrically isolate grounded chuck susceptor 212 and electrode 216. In addition, electrode 216 is a biasable electrode.

As illustrated in FIG. 2, RF power is coupled to electrode 216 from second RF generator 280 through second electrode match network 282, blocking capacitor 284, and second electrode RF transmission line 286. In addition, substrate (e.g., a semiconductor wafer or LCD panel) 270 is shown on electrode 216. Desirably, the second electrode is utilized to attract the population of positively charged ions to the wafer surface. More specifically, the plasma source RF power controls the ion density while the chuck RF power controls the ion energy.

For example, first RF generator 290 delivers RF power (e.g., in the range of 1 to 5 kW) to ICP source. At substantially the same time, second RF generator 280 delivers RF power (e.g., in the range of 100 W to 3 kW) to electrode 216. The RF energy applied in the presence of process gases (e.g., at a pressure of 1 to 1000 mTorr) ignites plasma within reaction chamber in the region above wafer 270.

VAR assembly 230 comprises housing 232 and vertically translatable gas injection electrode 300, which is shown in detail in FIG. 3. Double-headed arrow 235 shows directions of movement for the injection plate in the vertically translatable gas injection electrode 300.

FIG. 3 illustrates an expanded view of a vertically translatable gas injection electrode for a VAR plasma source according to the present invention. Vertically translatable gas inject electrode 300 includes mounting plate 305, a plurality of translators 310, a plurality of translation means 315, coupling rod 320, structural member 325, enclosure 330, bellows 335, skirts 337, and injection plate 340. In alternate embodiments, mounting plate 305 and/or structural member 325 are not required. Desirably, controller 160 (FIG. 1) is operatively coupled to the plurality of translation means 315.

Double-headed arrow 350 shows directions of movement for injection plate 340. Clearance gap 345 between injection plate 340 and the inside wall of enclosure 330 allows such movement. Skirts 337 protect bellows 335 from RF energy as injection plate 340 is moved within the chamber. Skirts 337 are designed to minimize their impact on the plasma uniformity. For example, slots and material properties are chosen to minimize energy loss. In addition, skirts 337 are temperature controlled to minimize particle release from surface depositions.

In a preferred embodiment, a drive mechanism comprises a translator and a translation means responsively coupled to the translator. Desirably, a drive mechanism comprises a screw jack as a translator and motor drive as a translation means. For example, drive mechanisms can be lead screw driven linear stages capable of providing vertical movement of the gas inject electrode relative to the plasma source and the chuck assembly. Desirably, three drive mechanisms are used and spaced at equal distances azimuthally, i.e. every 120 degrees (only two drive mechanisms are shown in FIG. 3). Since linear drive mechanism components are well known in the art and are readily available for integration into the apparatus of the present invention the details of these components, including lead screws, linear bearings, electrical drive motors, controllers, limit switches, and the like will not be described. It will be appreciated by those of skill in the art that different methods of providing vertical translation of gas inject electrode relative to the plasma source and chuck assembly (e.g. linear motors, pneumatic devices) may be provided and such methods fall within the scope of the invention. These elements are interrelated as shown in FIG. 3.

Injection plate 340 includes a plurality gas orifices 342 fed gas through gas supply channels 344 from gas supply system 150 (FIG. 1). In a preferred embodiment, injection plate 305 are fabricated from aluminum and anodized for contact with the plasma. It will be appreciated by those of skill in the art that different methods of introducing gas to the reaction chamber are possible and different means to fabricate the gas inject electrode (i.e. materials, methods of fabrication, etc.) are possible, and such designs fall within the scope of this invention.

In other embodiments, injection plate 305 can include layers of inject plates stacked together wherein the bottom-most inject plate is fabricated from a material such as silicon. The material for the gas injection plate may be chosen specifically for a particular process. For instance, a silicon gas inject electrode may be desirable for oxide etch applications in that it is compatible with the etch process and etched silicon can act as a fluorine radical scavenger. In addition, the bottom-most inject plate can also include an edge comprising a material tuned to optimize the uniformity of a process. Also, the bottom-most inject plate can include materials having thickness profiles and/or doping profiles that are optimize for etch or deposition processes.

The gas injection plate 305 can be vertically translated via drive mechanisms discussed above. A tight clearance (i.e. ˜2 mm.) is provided between the gas inject plate and the outer wall of enclosure 340. Rod 320 is used to translate movement from the drive mechanism to the injection plate. In a preferred embodiment, rod 320 is also used to provide process gases to injector plate 340. Bellows 325 is extendably connected between the upper surface of the gas injection plate and the bottom surface of enclosure 330. The bellows 325 preserves the vacuum integrity while allowing movement of the gas injection plate 340.

In operation, upon command from controller 160 shown in FIG. 1 and in accordance with empirical data stored in controller (shown in FIG. 1) first translation means, second translation means, and third translation means (not shown) drive the vertically translatable gas inject electrode to an optimized setting for the selected wafer etch process step. In doing so, the translation of the gas inject electrode leads to a variation of the (cylindrical) plasma source aspect ratio (height-to-diameter). This step optimizes etch uniformity for the current wafer process and can be repeated in order to dynamically regulate the aspect ratio to control the uniformity during the process.

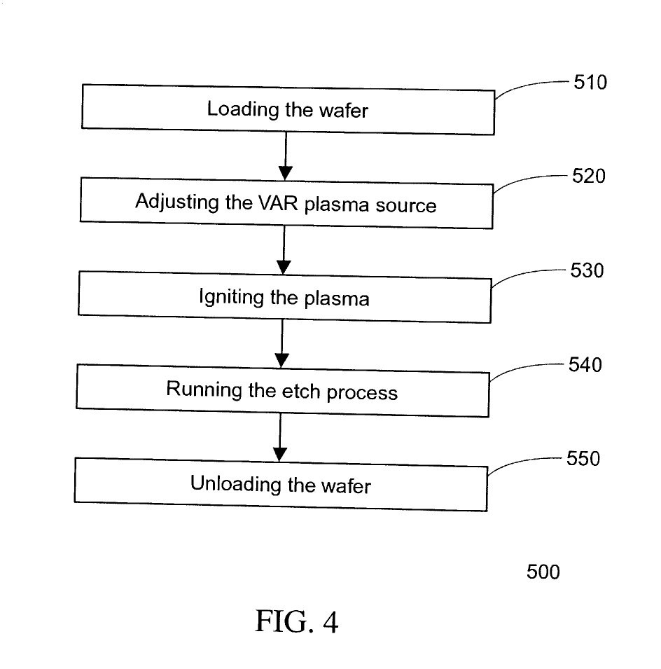

FIG. 4 illustrates a flowchart illustrating a method of using the variable aspect ratio plasma source according to the present invention. Procedure 500 shows a method of operating the apparatus of the present invention to optimize etch uniformity. Procedure 500 begins with step 510.

In step 510, a wafer is placed upon the chuck assembly 210 via conventional means (e.g., transfer system robotic arm and lift pins, etc.) in the reaction chamber 205.

In step 520, the VAR plasma source receives commands from the controller to achieve an optimum height-to-diameter ratio for the current wafer etch process. By adjusting the height of the vertically translatable gas inject electrode relative to the wafer, the radial component of the plasma density and electron density are optimized. For example, the optimal position for the vertically translatable gas inject electrode can be determined from wafer blanket and patterned etch tests completed a priori.

Alternatively, the optimal position of the vertically translatable gas inject electrode relative to the wafer may be determined and/or re-determined in-situ once a plasma has been generated via spatially resolved optical emissions. For example, U.S. patent application Ser. No. 60/193,250 describes a technique for monitoring and recording spatially resolved (in a transverse directions parallel with the wafer surface) plasma optical emissions via optical spectroscopy, entitled “Optical monitoring and control system and method for plasma reactors”. This application is herein incorporated by reference in its entirety.

In addition, the optimal position of the vertically translatable gas inject electrode relative to the wafer may be determined and/or re-determined in-situ once a plasma has been generated via microwave measurements. For example, U.S. patent application Ser. Nos. 60/144,880; 60/144,833; 60/144,878; and 60/166,418 describe techniques for using microwave devices to make plasma density measurements. These applications are herein incorporated by reference in their entirety.

In step 530, the chamber is evacuated by the vacuum pumping system to a base pressure (e.g. 0.1 to 1 mTorr), process gas is introduced to the vacuum chamber at a prescribed flow rate (e.g., equivalent to 100 to 1000 sccm argon), and the gate valve (or vacuum pump throttle valve) is partially closed to achieve the desired process pressure (e.g. 1 to 100 mTorr). Following the introduction of an ionizable gas to the process chamber, RF power is provided to the first electrode (inductive coil) and second electrode (chuck electrode), and the plasma is generated.

The etch process is run with a first set of operational parameters. The first set of operational parameters comprise process type, process time, chamber pressure, temperature, process gases, flow rates, first RF generator power, and second RF generator power. In some processes, the aspect ratio of the plasma source is adjusted during the process to achieve optimum wafer etch uniformity.

In another embodiment, a deposition process can be run with operation parameters optimized during the deposition process.

In step 540, the wafer can be unloaded or removed from the reaction chamber (e.g., again by conventional means).

To further improve etch uniformity, the etch uniformity on the wafer can be analyzed. The analysis results can be stored and used to recalculate the optimal position used for the vertically translatable gas inject electrode for another wafer or another set of wafers.

In addition, the controller can dynamically adjust a height-to-diameter ratio of a VAR plasma source for different wafer processes including trench etching and/or via etching processes. The controller can dynamically adjust a height-to-diameter ratio of the VAR plasma source to maintain radial plasma density uniformity while operational parameters vary over a wide range of wafer compositions, configurations and/or processes. The controller can dynamically adjust a height-to-diameter ratio of the VAR plasma source to provide a plasma source that can change processes dynamically, that is, to etch or deposit stacks of material and tune the process optimally for each layer. For example, the ratio can be changed for break-thru, main etch, and over-etch conditions. The ratio can also be dependent upon the material such as silicon compounds and/or gallium compounds.

In an alternative embodiment, a vertically moveable lower electrode is utilized (instead of or in addition to a moveable upper electrode). A vertically moveable lower electrode allows the exhaust manifold effect to be tuned and allows the amount of sidewall, which is available to act as a ground electrode for a parallel plate plasma, to be tuned.

Numerous modifications and variations of the present invention are possible in light of the above teachings. It is therefore to be understood that, within the scope of the appended claims, the invention may be practiced otherwise than as specifically described herein.

1. A plasma processing system for processing a plurality of wafers comprising:
plasma processing chamber;
variable aspect ratio (VAR) plasma source coupled to the plasma processing chamber for adjusting a height-to-diameter ratio of the plasma processing chamber;
first RF generator electrically coupled to the VAR plasma source;
second RF generator electrically coupled to the VAR plasma source;
gas supply system fluidly coupled to the VAR plasma source;
cooling system hydraulically coupled to the VAR plasma source; and
controller operatively coupled to the VAR plasma source, the first RF generator, the second RF generator, the gas supply system, and the cooling system, the controller for determining a first height-to-diameter ratio for a first wafer and for determining a second height-to-diameter ratio for a second wafer.

2. The plasma processing system as recited in claim 1, wherein the VAR plasma source comprises:
vertically translatable gas injection electrode; and
housing coupled to the vertically translatable gas injection electrode.

3. The plasma processing system as recited in claim 2, wherein the vertically translatable gas injection electrode comprises:
enclosure coupled to the housing, the enclosure defining a first region and a second region in the housing;
plurality of drive mechanisms coupled to the housing in the first region and operatively coupled to the controller;
gas injection plate mounted in the second region;
coupling rod coupled to the plurality of drive mechanisms in the first region and to the gas injection plate in the second region; and
bellows coupled to the gas injection plate and the enclosure, the bellows isolating the first region from the second region.

4. The plasma processing system as recited in claim 3, wherein each of the plurality of drive mechanisms comprises:
translator coupled to the enclosure and to the coupling rod; and
translation means responsively coupled to the translator and operatively coupled to the controller.

5. The plasma processing system as recited in claim 3, wherein each of the plurality of drive mechanisms comprises:
screw drive coupled to the enclosure and to the coupling rod; and
motor drive responsively coupled to the screw drive and operatively coupled to the controller.

6. A variable aspect ratio (VAR) plasma source comprising:
plasma source assembly including a process chamber;
chuck assembly coupled to the plasma source assembly; and
VAR assembly coupled to the plasma source assembly for adjusting a height-to-diameter ratio of the process chamber, a first height-to-diameter ratio being established for a first wafer and a second height-to-diameter ratio being established for a second wafer.

7. The VAR plasma source as recited in claim 6, wherein the VAR assembly comprises:
enclosure coupled to the plasma source assembly;
a plurality of drive mechanisms rigidly coupled to the enclosure, each of the plurality of drive mechanisms comprising at least one control input and at least one control output;
coupling rod coupled to the plurality of drive mechanisms;
gas injection plate coupled to the coupling rod; and
bellows coupled to an inside surface of the enclosure and to a top surface of the gas injection plate, the bellows enclosing a portion of the coupling rod, wherein a first region is defined inside the bellows, a second region is defined outside the bellows, and the first and second regions are isolated from each other.

8. The VAR plasma source as recited in claim 7, wherein each of the plurality of drive mechanisms comprises:
screw drive coupled to the enclosure and to the coupling rod; and
motor drive responsively coupled to the screw drive.

9. The VAR plasma source as recited in claim 7, wherein each of the plurality of drive mechanisms comprises at least one linear motor coupled to the coupling rod.

10. The VAR plasma source as recited in claim 7, wherein each of the plurality of drive mechanisms comprises at least one pneumatic device coupled to the coupling rod.

11. A method of operating a variable aspect ratio (VAR) plasma source to optimize etch uniformity, the method comprising the steps of:
placing a wafer on a first electrode in the variable aspect ratio plasma source;
positioning a vertically translatable gas inject electrode at a first position relative to the first electrode, in the variable aspect ratio plasma source, the first position being based on a first set of operational parameters;
etching the wafer by generating a plasma using the first set of operational parameters, the first set of operational parameters comprising process type, process time, chamber pressure, temperature, process gases, flow rates, first RF generator power, and second RF generator power; and
unloading the wafer.

12. The method of operating a VAR plasma source as recited in claim 11, wherein the method further comprises the steps of:
analyzing etch uniformity on the wafer; and
determining a second set of operational parameters using analysis results.

13. The method of operating a VAR plasma source as recited in claim 11, wherein the etching step further comprises the steps of:
monitoring at least one of the first set of operational parameters; and
re-positioning the vertically translatable gas inject electrode based on the monitoring step.

14. The method of operating a VAR plasma source as recited in claim 11, wherein the etching step further comprises the steps of:
monitoring the wafer; and
re-positioning the vertically translatable gas inject electrode based on the monitoring step.

15. The method of operating a VAR plasma source as recited in claim 11, wherein the positioning step further comprises the step of determining the first position for the vertically translatable gas inject electrode using data from wafer blanket tests.

16. The method of operating a VAR plasma source as recited in claim 11, wherein the positioning step further comprises the step of determining the first position for the vertically translatable gas inject electrode using data from patterned etch tests.

17. The method of operating a VAR plasma source as recited in claim 11, wherein the method further comprises the step of repositioning the first electrode.

18. A method of operating a variable aspect ratio (VAR) plasma source to optimize deposition uniformity, the method comprising the steps of:
placing a wafer on a first electrode in the variable aspect ratio plasma source;
positioning a vertically translatable gas inject electrode at a first position, relative to the first electrode, in the variable aspect ratio plasma source, the first position being based on process parameters established to optimize a radial component of a plasma density;
depositing a layer of material on the wafer by generating a plasma using the process parameters, the process parameters comprising process type, process time, chamber pressure, temperature, process gases, flow rates, first RF generator power, and second RF generator power; and
unloading the wafer.

19. In a plasma processing apparatus, the improvement comprising:
a variable aspect ratio (VAR) assembly, inside a plasma chamber, carrying at least one of an upper electrode and a lower electrode for varying a height-to-diameter ratio of the plasma chamber.

20. The apparatus as claimed in claim 19, the improvement further comprising a controller for controlling a height position of the VAR assembly.

21. The apparatus as claimed in claim 19, the improvement further comprising an injection plate translated by a plurality of drive mechanisms.

22. The apparatus as claimed in claim 21, the improvement further comprising at least one screw jack for controlling a height position of the injection plate.
